(19) United States
(12) Patent Application Publication
(10) Pub. No.: US 2026/0287647 A1
(43) Pub. Date: Sep. 24, 2026

(54) RELIABILITY TEST PLATFORM AND PROBE PAD ASSEMBLY

(71) Applicant: MetaPWR Electronics Co., Ltd., Shanghai (CN)

(72) Inventors: Jiakun DU, Shanghai (CN); Xiaoni Xin, Shanghai (CN); Yayu LI, Shanghai (CN); Jianhong ZENG, Shanghai (CN); Deqin DU, Shanghai (CN)

(73) Assignee: MetaPWR Electronics Co., Ltd., Shanghai (CN)

(21) Appl. No.: 19/574,453

(22) Filed: Mar. 23, 2026

(30) Foreign Application Priority Data
Mar. 24, 2025 (CN) 202510351014.6

(51) Int. Cl. G01R 31/28; G01R 1/04; G01R 1/067; G01R 1/20

(52) U.S. Cl. CPC G01R 31/2879; G01R 1/0416; G01R 1/06722; G01R 1/203; G01R 1/206; G01R 31/2863; G01R 31/2877

(57) ABSTRACT

The present invention discloses a comprehensive solution for a reliability test platform that satisfies the demands of high-current and dynamic response characteristics for the loads of DC/DC converter. Furthermore, by implementing energy feedback through the load assembly, the system significantly reduces losses on energy transmission path by recycling the majority of output energy back to the power grid. Additionally, the invention discloses a structural configuration for the test card that minimizes losses along the transmission path by setting the load assembly, the Device Under Test (DUT), and associated interconnects. The disclosed probe pad structure also addresses the need for high-output-current while reducing thermal losses and operational temperatures within the probe interface, thereby ensuring stable and reliable operation of the entire test platform.

### CROSS-REFERENCE TO RELATED APPLICATION

This application claims the priority benefit of China application serial no. 202510351014.6 filed on Mar. 24, 2025. The entirety of the above-mentioned patent application is hereby incorporated by reference herein and made a part of this specification.

### BACKGROUND

### Description of Related Art

Currently, power supplies for large-scale integrated chips such as GPUs, CPUs, and DPUs typically employ VRMs (Voltage Regulator Modules). The VRM steps down the output voltage (greater than 2V) of the Intermediate Bus Converter (IBC) to the supply voltage(less than 2V) required by the chips. Given that the reliability of the VRM directly impacts the reliability of the chips, VRM reliability testing is a very critical part of both the R&D and production.

In VRM reliability testing, VRMs must operate under full-load conditions for several hours to several thousand hours, with a large number of VRMs tested simultaneously. Existing testing approaches include two methods. First, using resistors as a load for VRM, which converts all electrical energy into heat, resulting in high energy consumption and stringent thermal management requirements—making this approach unsuitable for high-volume VRM testing. Second, connecting multiple test VRMs in series to feed into an inverter that returns the electrical energy output by the VRMs back to the power grid. While this method is more energy-efficient and environmentally friendly, it has a relatively high implementation cost. Moreover, if any single VRM fails, the entire series circuit becomes inoperative, rendering this approach unsuitable for testing the lifetime distribution of VRMs.

Additionally, during final inspection of the VRM or other power conversion device, products must not exhibit any physical damage, so they cannot be soldered to the substrate for testing. Instead, the devices must be placed on a probe test socket for testing. As the output current of the devices increases, the probe test socket must have a current handling capability exceeding 50 A. However, the probe test socket in the prior art lacks sufficient current handling capability, necessitating the urgent development of a probe test socket with a simple structure, high current handling capability, and low parasitic impedance.

### SUMMARY

In view of the above, one of the objectives of the disclosure is to a reliability test platform, comprising a device under test, a low-voltage bus, and a load assembly; wherein the device under test comprises a buck converter unit, an input of the device under test is electrically connected to the low-voltage bus, an output of the device under test is electrically connected to an input of the load assembly, and an output of the load assembly is electrically connected to the low-voltage bus; and the load assembly comprises at least a BOOST converter unit.

Preferably, wherein the load assembly further comprises a variable resistor load, wherein the variable resistor load is used to simulate variations in load current.

Preferably, wherein the variable resistor load comprises at least one resistor and at least one switch, and the resistor and switch are electrically connected in series and connected across the output of the device under test.

Preferably, wherein the BOOST converter unit comprises a DC/DC boost converter, wherein the output of the DC/DC boost converter is electrically connected to the low-voltage bus.

Preferably, further comprising a motherboard and a test substrate, wherein the device under test and the load assembly are mounted on the test substrate; the test substrate comprises a connector, the test substrate is mounted to the motherboard, and the test substrate is electrically connected to the motherboard by means of the connector.

Preferably, wherein the test substrate further comprises mounting holes, the test substrate is mounted to the motherboard by means of the mounting holes and parallel to the motherboard; the connector comprises a power connector and a signal/auxiliary power connector, wherein the connectors are positioned on a bottom surface of the test substrate; and the device under test and the load assembly are mounted on a top surface of the test substrate.

Preferably, wherein the connector is positioned on one side of the test substrate, the test substrate is mounted to the motherboard vertically and electrically connected to the motherboard by means of the connector; and the load assembly and the device under test are mounted on a top surface and/or a bottom surface of the test substrate.

Preferably, wherein the device under test is mounted on an adapter board, wherein the adapter board comprises an adapter connector positioned on one side of the adapter board; the adapter board is mounted to the test substrate vertically and electrically connected to the test substrate by means of the adapter connector.

Preferably, wherein the adapter connector is a gold finger, wherein the test substrate includes a slot, and the gold finger is inserted into the slot.

Preferably, wherein the device under test is mounted on an adapter board, wherein the adapter board comprises an adapter connector positioned on a bottom surface of the adapter board; the adapter board is electrically connected to the test substrate by means of the adapter connector, and the adapter board is parallel to the test substrate.

Preferably, wherein t the adapter connector is a metal pin, wherein the test substrate includes a adapter board socket, and the metal pin is inserted into the transfer board socket.

Preferably, wherein heat sinks are mounted on the load assembly and/or the device under test, wherein the heat sinks are mounted to the test substrate.

Preferably, wherein t the device under test is electrically connected to the test substrate by means of soldering or a probe test socket.

Preferably, wherein it further comprises a motherboard, a test card, a control card, and a power conversion card; wherein the device under test and the load assembly are mounted on the test card; the test card, the control card, and the power conversion card are mounted to the motherboard; and the power conversion card employs a DC/DC buck converter, wherein an output of the power conversion card is electrically connected to the low-voltage bus, and the control card controls and/or monitors the power conversion card, the device under test, and the load assembly.

Preferably, wherein the power conversion card, the control card, and the test card are independent hardware units mounted to the motherboard by means of connectors.

Preferably, wherein the first side of the motherboard includes a test cabinet interface, the power conversion card is positioned between the test cabinet interface and the control card, the control card is positioned at the center of the motherboard, and the test cards are adjacent to the control card.

Another object of the invention is to disclose a probe pad assembly, comprising a probe pad base plate, a probe pad cover, and a spring probe; wherein the spring probe includes a probe cap, a spring, and a probe core; the probe core is mounted to the probe pad base plate; the spring is mounted on the probe core; the probe cap is mounted on an upper end of the spring; one end of the probe core is electrically connected to and fixed on a test substrate; the probe cap contacts and electrically connects to a device under test; the probe pad cover is mounted to the probe pad base plate; and the probe cap protrudes from a top surface of the probe pad cover.

Preferably, wherein the probe pad assembly is soldered to the test substrate in a surface mount soldering, and the probe cores of the same electrical network are electrically connected to the same pad on the test substrate.

Preferably, wherein the probe pad base plate is a printed circuit board or a ceramic substrate.

Preferably, wherein the probe core is a metal block welded to the probe pad base plate; the metal block includes a spring hole, and at least part of the spring and the probe cap are positioned within the spring hole.

Preferably, wherein multiple spring holes are formed on the metal block, and the probe cores within the multiple spring holes are electrically connected to the same electrical network.
(1) The present invention discloses a reliability test platform capable of meeting the high-current and dynamic response characteristics requirements of DC/DC conversion devices. The platform further reduces energy loss by feeding the majority of the energy back to the power grid through the load assembly.
(2) Additionally, the invention provides a structural arrangement for the test card that minimizes energy loss in the transmission path by arranging the load assembly, the device under test (DUT), and the connectors.
(3) Furthermore, the invention discloses a structural arrangement for the test probe pad assembly that satisfies high-output-current requirements of the DUT while simultaneously reducing power dissipation and operating temperature on the probe pad, thereby ensuring stable and reliable operation of the test platform.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1-4 are a structural arrangement of the reliability test platform;

FIGS. 5A-5C to are a structural arrangement of the test card;

FIGS. 6A-6B are another structural arrangement of the test card;

FIGS. 7A-7B are another structural arrangement of the test card;

FIGS. 8A-8C are another structural arrangement of the test card;

FIG. 9 is a structural arrangement of the reliability test platform;

FIG. 10 is a prior art of the spring probe; and

FIGS. 11-13 are a structural arrangement of the probe pad assembly.

### DESCRIPTION OF THE EMBODIMENTS

One of the cores of the present disclosure is to provide a reliability test platform and a probe pad assembly.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

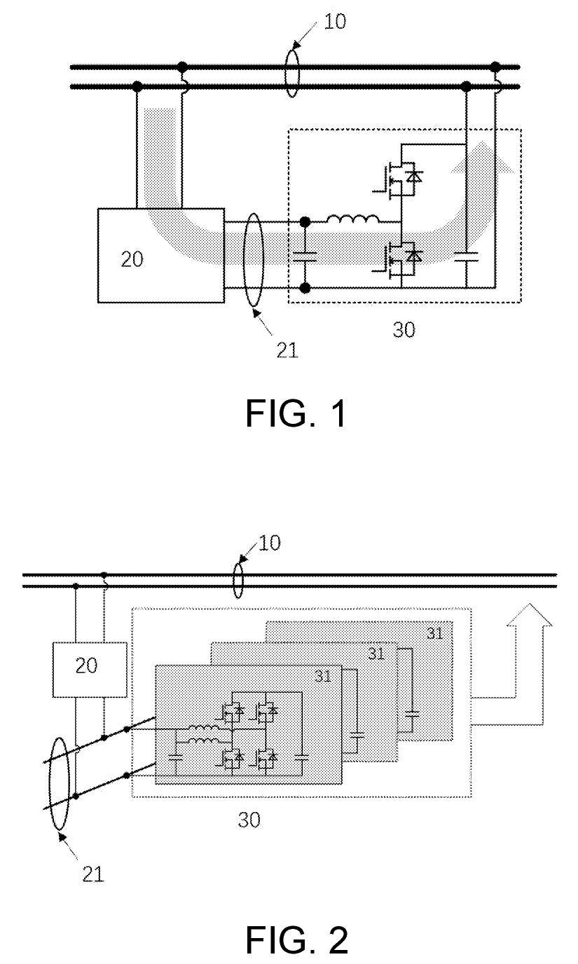

The present invention discloses a method for utilizing a BOOST converter as a reliability test load for Voltage Regulator Modules (VRMs). However, the reliability test method disclosed herein is not limited to VRMs serving as the Device Under Test (DUT); other DC/DC converters may also be subjected to testing using this methodology. As shown in FIG. 1, an input of the DUT and an output of the load assembly 30 are both connected to a low-voltage bus 10. An output 21 of the DUT 20 is connected to an input of the load assembly 30, and the majority of the output power from the DUT 20 is fed back to the low-voltage bus 10 through the load assembly 30. The flow path and direction of this energy are indicated by a gray arrow in FIG. 1. Compared to a resistive load implementation, using the BOOST load for energy recovery can reduce the losses of energy transmission path by at least 80%.

Furthermore, the power of the load assembly can be increased by paralleling multiple phases of BOOST converters. At least one phase of the BOOST converter is served as a load unit 31, when load power expansion is needed, the number of the load unit 31 can be increased. As shown in FIG. 2, taking the load unit 31 formed by two phases of BOOST converters as an example, wherein the load assembly 30 includes three load units 31, all inputs of the load units 31 are paralleled and electrically connected to the output of the DUT 20, and all outputs of the load units 31 are paralleled and electrically connected to the low-voltage bus 10.

Furthermore, in certain test scenarios that requiring rapid current changes, the BOOST load may fail to achieve the required output current slew rate of the DUT 20, wherein the output current slew rate may reach 1000 A/μs or even more than 5,000 A/μs. The present invention adds an additional variable resistor load 32, wherein the variable resistor load 32 comprises at least one resistor and at least one switch, the switch is optimally a semiconductor power device. The resistor and the switch are connected in series and then connected across the output terminals (i.e., the positive output terminal and negative output terminal) of the DUT. The variable resistor load 32 may include multiple series-connected branches of the resistor and the switch, the voltage amplitude and the slew rate are driven by configuring different resistance values and controlling different switches for meeting the dynamic test application of the load.

To facilitate maintenance and upgrades of the load assembly, the reliability test platform employs a modular design, as shown in FIG. 4. The reliability test platform comprises at least one test card 1, at least one control card 2, at least one power conversion card 3, and a motherboard 4. As shown in FIG. 4, the reliability test platform is exemplified with test cards 1a, 1b and 1c, control cards 2a, 2b and 2c, and power conversion cards 3a, 3b and 3c. The power conversion card 3 implements a DC/DC buck converter to transform high-voltage power (above the input voltage of the DUT 20) into the input voltage of the DUT 20. For the DUT 20 with low input voltage, the power conversion card 3 provides a more stable input voltage. Additionally, the power conversion card 3 functions as an independent hardware unit arranged adjacent to the test card 1. The control card 2 functions as an independent hardware unit used for controlling and monitoring both the test card 1 and the power conversion card 3. External communication of the reliability test platform may also be achieved by means of the control card 2. The entire test platform may comprise multiple control cards, each performing identical or distinct functions. The test card 1, the control card 2, and the power conversion card 3 are mounted to the motherboard 4 by means of connecters.

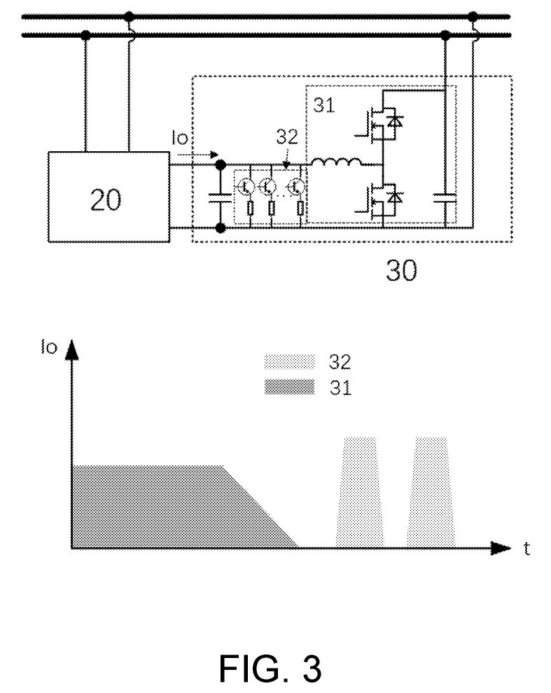

In another embodiment, the present invention discloses a structure arrangement of the test card such as 5A to 5C. FIG. 5A is a top schematic diagram of the test card, FIG. 5B is a bottom schematic diagram of the test card, and FIG. 5C is a side schematic diagram of the test card. In this embodiment, the test card 1 is used for verifying the reliability of a single power product. The test card 1 includes a test substrate 50, a pad or a test socket probe contact (referred to as contact) 51, a fixed hole 52, the load assembly 30, a power connector 53 and a signal/auxiliary electrical connector 54. The test card 1 is fixed on the motherboard b(not shown) by the fixed hole 52, and the test substrate 50 is parallel to the motherboard 4; the power connector 53 and the signal/auxiliary electrical connector 54 are arranged on the bottom of the test substrate 50, and the test card 1 is connected to the motherboard 4 by means of the power connector 53 and the signal/auxiliary electrical connector 54. The DUT 20 can be directly welded onto the pad or can be electrically connected with the test substrate 50 by means of the probe of the test socket assembled on the test substrate 50.

The test card 1 also includes a test socket mounting hole 56, a DUT heatsink mounting hole 55, a load assembly heatsink mounting hole 58, and a load assembly heatsink 57. A top surface of the load assembly 30 is mounted with the load assembly heatsink 57, which is mounted to the test substrate 50 by means of the load assembly heatsink mounting hole 58. The test socket is mounted to the test substrate 50 by means of the test socket mounting hole 56. The DUT 20 may be provided with a heatsink which is mounted to test substrate 50 by means of the DUT heatsink mounting holes 55.

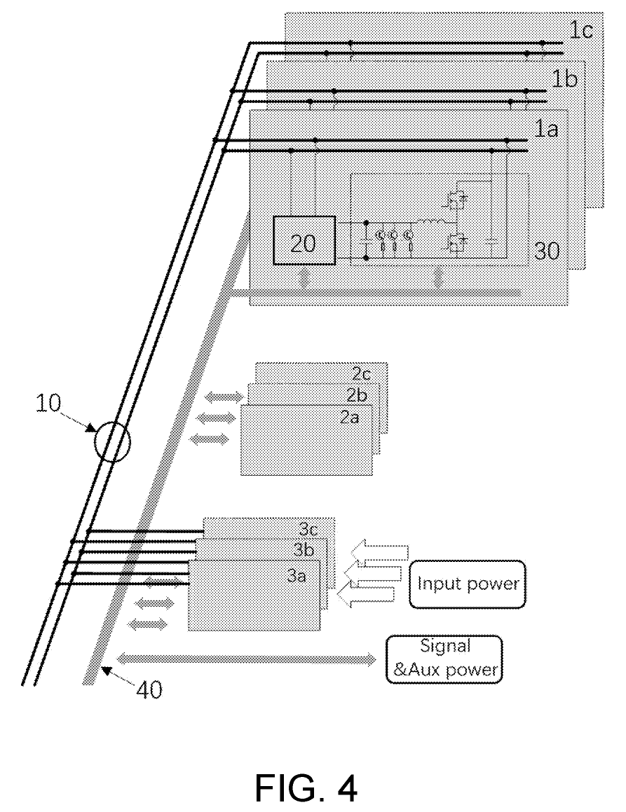

Optionally, as shown in FIGS. 6A and 6B, an alternative structural arrangement for the test card is provided. FIG. 6A is a top view of the test card. FIG. 6B is a side view of the test card. The DUT 20 is welded to the test substrate 50 by means of the pad 51. The heatsink on the top surface of the DUT 20 is mounted to the test substrate 50 by means of the DUT heatsink mounting hole 55. The load assembly 30 may be mounted on the top and/or the bottom surface of the test substrate. The load assembly heatsink 57 is assembled on the top surface of the load assembly 30. The test card 1 is vertically mounted on the motherboard 4. The test card 1 is mounted on the motherboard 4 by means of a gold finger 59 or other types of connectors and is electrically connected to the motherboard 4.

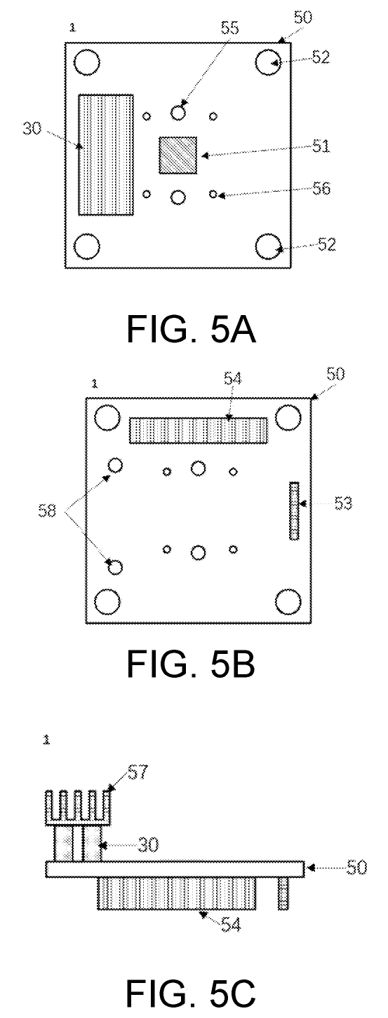

Optionally, as shown in FIGS. 7A and 7B, the test card 1 may be electrically connected to the motherboard 4 by means of the connectors (not shown) and mounted to the motherboard 4 by means of the mounting holes 52. When the test card 1 is mounted to motherboard 4, the test substrate 50 is parallel with the motherboard 4. The DUT 20 is welded to an adapter board 60 by means of the pad 51. The heatsink on the top surface of the DUT 20 may be mounted to the adapter board 60 by means of the heatsink mounting holes 55. The DUT 20 is mounted to and electrically connected to a slot 61 arranged on the test substrate 50 by means of the gold fingers 59 and the adapter board 60 is vertically mounted on the test substrate 50.

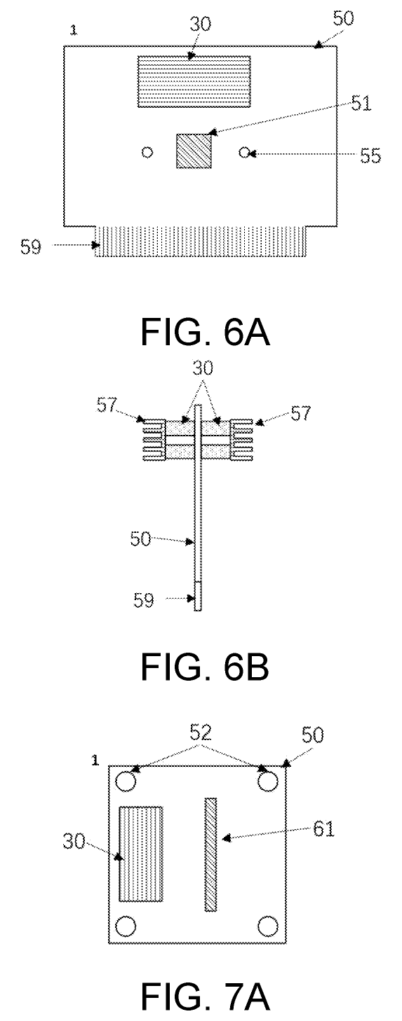

Optionally, as shown in FIGS. 8A-8C, another structural arrangement for the test card is provided. FIG. 8A is a top view of test card 1. FIG. 8B is a top view of the adapter board. FIG. 8C is a side view of the adapter board. The test card 1 is parallel-mounted to the motherboard 4 by means of the fixed hole 52. The Load assembly 30 and an adapter board slot 62 are mounted on the top surface of the test substrate 50. The DUT 20 is welded to the adapter board 60 by means of the pad 51, and the heatsink on the top surface of the DUT 20 is mounted to the adapter board 60 by means of the DUT heatsink mounting holes 55. The bottom surface of the pad 51 (i.e., the bottom surface of the adapter board 60) is provided with metal pins 63, the adapter board 60 is mounted to the adapter board slot 62 by means of the metal pins 63 and the DUT 20 is electrically connected to the test substrate 50 through the metal pins 63.

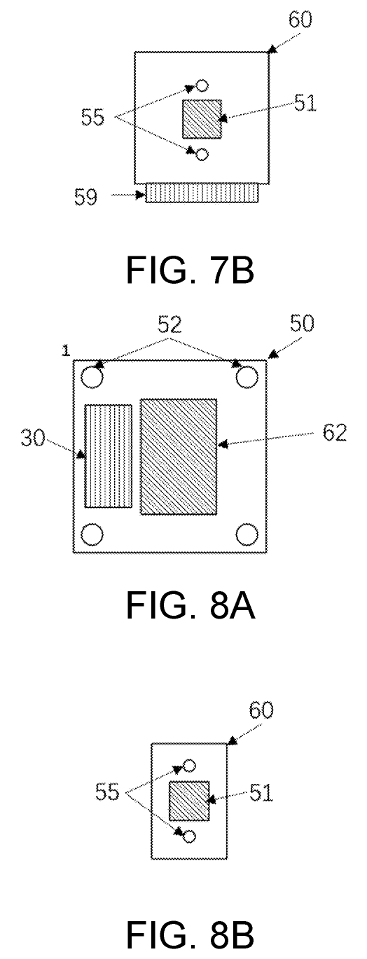

The present invention also discloses a structural arrangement for the reliability test platform, as shown in FIG. 9. The reliability test platform employs a modular design and comprises at least one test card 1, at least one control card 2, at least one power conversion card 3, and the motherboard 4. In this embodiment, the reliability test platform comprises eight test cards 1a, 1b, 1c, 1d, 1e, 1f, 1g and 1h, two control cards 2a and 2b, one power conversion card 3, and the motherboard 4. The control cards 2a and 2b are positioned along the horizontal midline of the motherboard 4 (i.e., the central of the motherboard 4). The test cards 1a, 1b, 1e and 1f are adjacent to the control card 2a. In this embodiment, four test cards 1a, 1b, 1e and 1f are arranged in a 2x2 array, with the control card 2a positioned at the center of the array. Similarly, four test cards 1c, 1d, 1g and 1h are arranged in another 2x2 array, with the control card 2b positioned at the center of the array. A test cabinet interface 64 and a handle 65 are arranged adjacent to a first side 401 and a third side 403 of the motherboard 4, respectively; the power conversion card 3 is arranged between the test cabinet interface 64 and the control card 2a. The structural arrangement of all the test cards may adopt the aforementioned embodiments and can achieve the same technical effects. The mounting methods between the control cards and the motherboard 4, as well as between the power conversion cards and the motherboard 4 are not limited, and may adopt the mounting method between the test card and the motherboard 4.

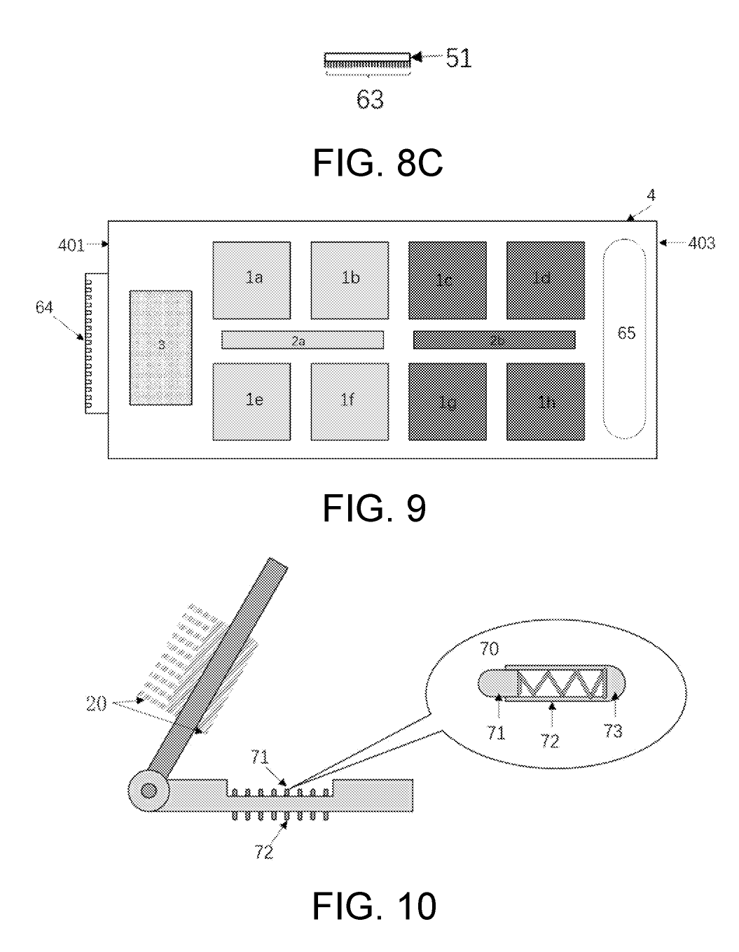

In the prior art, the core component of a probe test socket is a spring probe, the DUT is electrically connected with the test substrate by means of the spring probes. To increase the current-carrying capacity of the test socket, it is necessary to minimize the impedance of per probe and maximize the number of the probes—both of which are difficult challenges in the prior art. Taking a common spring probe structure shown in FIG. 10 as an example, the spring probe comprises a movable plunger 71, a stationary barrel 73, and a spring 72. The stationary barrel 73 is welded and fixed to the test substrate 50 and the movable plunger 71 is used for contacting the DUT. This structure is relatively complex, wherein the spring probe requires expensive materials, such as gold or silver, to reduce impedance; the manufacturing precision of the movable plunger and the stationary barrel need to be improved to minimize gaps between them, and a stronger spring is needed to increase contact pressure. Additionally, under the constraint of a fixed DUT pad area, increasing the number of probes necessitates reducing the probe diameter and inter-probe spacing - demanding higher precision, mechanical strength and conductivity of the probe, as well as higher strength of the insulating materials that holds the probe.

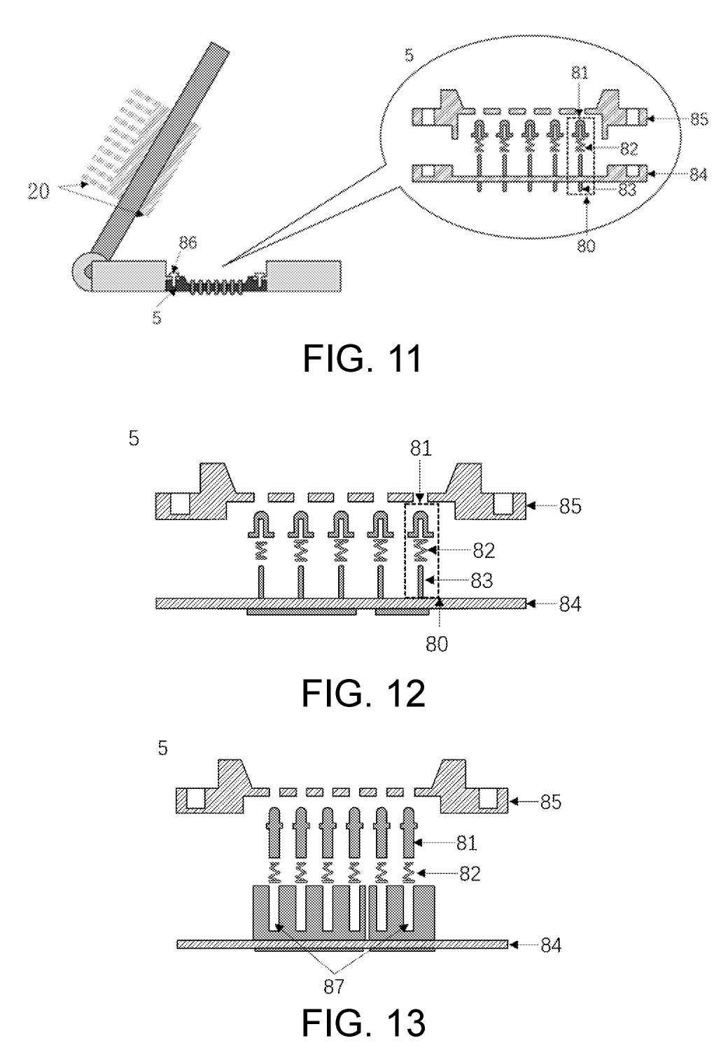

The present invention discloses a structural for a spring probe, a straight-insert probe test socket is shown in FIG. 11. The spring probe 80 comprises a probe cap 81, a probe core 83, and a spring 82. The probe core 83 is fixed to a probe pad base plate 84, the spring 82 is mounted on one end of the probe core 83, and the other end of the probe core 83 is electrically connected to the test substrate 50. The probe cap 81 contacts and electrically connects to the DUT and is capable of linear movement by means of the spring 82, at least part of the probe cap 81 is exposed from a probe pad cover plate 85. The probe pad cover plate 85 and the probe pad base plate 84 are high-temperature resistant plastic components and are integrally connected through adhesive or heat fusion. The spring probe 80, the probe pad cover plate 85, and the probe pad base plate 84 form a single unit referred to as probe pad 5. The Probe pad 5 is mounted to other components of the test socket by means of a screw 86, wherein during use, the probe pad 5 is first welded to the test substrate 50 before installing other components. One advantage of this solution is superior spring heat dissipation, preventing spring weakening due to high temperature, which could cause poor contact with pads, therefore leading to a vicious cycle of more severe heating and further spring weakening of the spring. Another advantage is the reduced contact impedance of the spring probe, since one end of the spring probe is directly welded to the test substrate 50, the contact impedance between the spring probe and the test substrate is eliminated.

Optionally, as shown in FIG. 12, the probe pad 5 may be soldered directly to the test substrate 50 in a surface mount soldering, where the probes in the same electrical network are electrically connected to the same pad. In this embodiment, the pin pad base plate 84 may be a printed circuit board or ceramic substrate.

Optionally, as shown in FIG. 13, the probe core 83 is a monolithic structure achieved by pre-drilling spring holes 87 in a copper block. The spring 82 is arranged in the spring hole 87, the probe cap 81 is mounted at the top end of the spring 82, and the copper block is welded to the probe pad base plate 84. In this embodiment, the probe pad base plate 84 may be a printed circuit board or ceramic substrate. The advantage of this embodiment is the low resistance of the copper block, further reducing spring probe impedance. Additionally, the thermal conductivity of the copper helps lower the operational temperature of the spring probe, ensuring reliable performance of the spring probe. The structural arrangement of the spring probes disclosed in the present invention can be applied to the aforementioned test cards and achieve same technical effects.

The " equal " or " same " or " equal to " disclosed by the application needs to consider the parameter distribution of engineering, and the error distribution is within +/-30%; and the included angle between the two line segments or the two straight lines is less than or equal to 45 degrees; the included angle between the two line segments or the two straight lines is within the range of [ 60, 120 ]; and the definition of the phase error phase also needs to consider the parameter distribution of the engineering, and the error distribution of the phase error degree is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A reliability test platform, comprising a device under test, a voltage bus, and a load assembly; wherein the device under test comprises a buck converter unit, an input of the device under test is electrically connected to the voltage bus, an output of the device under test is electrically connected to an input of the load assembly, and an output of the load assembly is electrically connected to the voltage bus; and the load assembly comprises at least a boost converter unit.

2. The reliability test platform of claim 1, wherein the load assembly further comprises a variable resistor load, wherein the variable resistor load is used to simulate variations in a load current.

3. The reliability test platform of claim 2, wherein the variable resistor load comprises at least one resistor and at least one switch, and one of the at least one resistor and one of the at least one switch are electrically connected in series and connected across the output of the device under test.

4. The reliability test platform of claim 1, wherein the boost converter unit comprises a DC/DC boost converter, wherein an output of the DC/DC boost converter is electrically connected to the voltage bus.

5. The reliability test platform of claim 1, further comprising a motherboard and a test substrate, wherein the device under test and the load assembly are mounted on the test substrate; the test substrate comprises a connector, the test substrate is mounted to the motherboard, and the test substrate is electrically connected to the motherboard by the connector.

6. The reliability test platform of claim 5, wherein the test substrate further comprises mounting holes, the test substrate is mounted to the motherboard by the mounting holes and parallel to the motherboard; the connector comprises a power connector and a signal/auxiliary power connector, wherein the power connector and the signal/auxiliary power connector are positioned on a bottom surface of the test substrate; and the device under test and the load assembly are mounted on a top surface of the test substrate.

7. The reliability test platform of claim 5, wherein the connector is positioned on one side of the test substrate, the test substrate is mounted to the motherboard vertically and electrically connected to the motherboard by the connector; and the load assembly and the device under test are mounted on a top surface and/or a bottom surface of the test substrate.

8. The reliability test platform of claim 5, wherein the device under test is mounted on an adapter board, wherein the adapter board comprises an adapter connector positioned on one side of the adapter board; the adapter board is mounted to the test substrate vertically and electrically connected to the test substrate by the adapter connector.

9. The reliability test platform of claim 8, wherein the adapter connector is a gold finger, wherein the test substrate comprises a slot, and the gold finger is inserted into the slot.

10. The reliability test platform of claim 5, wherein the device under test is mounted on an adapter board, wherein the adapter board comprises an adapter connector positioned on a bottom surface of the adapter board; the adapter board is electrically connected to the test substrate by the adapter connector, and the adapter board is parallel to the test substrate.

11. The reliability test platform of claim 10, wherein the adapter connector is a metal pin, wherein the test substrate comprises an adapter board socket, and the metal pin is inserted into the adapter board socket.

12. The reliability test platform of claim 5, wherein heat sinks are mounted on the load assembly and/or the device under test and mounted to the test substrate.

13. The reliability test platform of claim 5, wherein the device under test is electrically connected to the test substrate by soldering or a probe test socket.

14. The reliability test platform of claim 1, further comprises a motherboard, a test card, a control card, and a power conversion card; wherein the device under test and the load assembly are mounted on the test card; the test card, the control card, and the power conversion card are mounted to the motherboard; and the power conversion card comprises a DC/DC buck converter, wherein an output of the power conversion card is electrically connected to the voltage bus, and the control card controls and/or monitors the power conversion card, the device under test, and the load assembly.

15. The reliability test platform of claim 14, wherein the power conversion card, the control card, and the test card are independent hardware units mounted to the motherboard by connectors.

16. The reliability test platform of claim 15, wherein a first side of the motherboard is positioned with a test cabinet interface, the power conversion card is positioned between the test cabinet interface and the control card, the control card is positioned at the center of the motherboard, and the test card are adjacent to the control card.

17. A probe pad assembly, comprising a probe pad base plate, a probe pad cover, and a spring probe; wherein the spring probe comprises a probe cap, a spring, and a probe core; the probe core is mounted to the probe pad base plate; the spring is mounted on the probe core; the probe cap is mounted on an upper end of the spring; one end of the probe core is electrically connected to and fixed on a test substrate; the probe cap contacts and electrically connects to a device under test; the probe pad cover is mounted to the probe pad base plate; and the probe cap protrudes from a top surface of the probe pad cover.

18. The probe pad assembly of claim 17, wherein the probe pad assembly is soldered to the test substrate in a surface mount soldering, and a plurality of the probe cores of a same electrical network are electrically connected to a same pad on the test substrate.

19. The probe pad assembly of claim 18, wherein the probe pad base plate is a printed circuit board or a ceramic substrate.

20. The probe pad assembly of claim 18, wherein the probe core is a metal block welded to the probe pad base plate; the metal block comprises a spring hole, and at least part of the spring and the probe cap are positioned within the spring hole.

21. The probe pad assembly of claim 20, wherein a plurality of the spring holes are formed on the metal block, and the probe cores within the plurality of the spring holes are electrically connected to the same electrical network.
